(19) United States
(12) Patent Application Publication
(10) Pub. No.: US 2025/0364951 A1
(43) Pub. Date: Nov. 27, 2025

(54) DOHERTY AMPLIFIER CIRCUIT

(71) Applicant: Murata Manufacturing Co., Ltd., Nagaokakyo-shi (JP)

(72) Inventors: Kiichiro TAKENAKA, Nagaokakyo-shi (JP); Masatoshi HASE, Nagaokakyo-shi (JP)

(21) Appl. No.: 19/217,068

(22) Filed: May 23, 2025

(30) Foreign Application Priority Data
May 27, 2024 (JP) 2024-085593

(51) Int. Cl. H03F 1/02; H03F 1/32; H03F 3/60

(52) U.S. Cl. CPC H03F 1/0288; H03F 1/32; H03F 3/602; H03F 2200/192; H03F 2200/451

(57) ABSTRACT

A Doherty amplifier circuit includes a 90° hybrid coupler that includes an input terminal receiving a first input signal, a first output terminal outputting a first output signal on the basis of the first input signal, a second output terminal outputting, on the basis of the first input signal, a second output signal different in phase by 90° from the first output signal, and an isolation terminal whose isolation from the input terminal is ensured; a carrier amplifier that amplifies the first output signal to output a first amplified signal; and a peak amplifier that amplifies the second output signal to output a second amplified signal. The isolation terminal is a terminal which receives a second harmonic in the second harmonic frequency band of the first input signal.

### CROSS REFERENCE TO RELATED APPLICATION

This application claims priority from Japanese Patent Application No. 2024-085593, filed on May 27, 2024. The content of these applications are incorporated herein by reference in its entirety.

### BACKGROUND OF THE DISCLOSURE

### 1. Field of the Disclosure

The present disclosure relates to a Doherty amplifier circuit.

### 2. Description of the Related Art

Mobile communication devices such as a cellular phone include a power amplifier for amplifying the power of transmit signals. For example, when such a power amplifier is supplied with multiple signals having frequencies close to one another, these signals may cause intermodulation distortion (IMD) to occur, resulting in degradation of linearity. Therefore, to suppress the influence of such intermodulation distortion, a technique has been proposed in which harmonic waves are injected to a signal path on purpose so as to cancel the intermodulation distortion components. For example, Japanese Unexamined Patent Application Publication No. 2005-318373 discloses a distortion-compensating and power-amplifying device which compensates intermodulation distortion in such a manner that, after the output from the initial-stage amplifier is divided into a fundamental and a second harmonic and the phase and amplitude of the second harmonic are adjusted, the resulting second harmonic is added to the fundamental for input to a subsequent amplifier.

### BRIEF SUMMARY OF THE DISCLOSURE

The device described in Japanese Unexamined Patent Application Publication No. 2005-318373 compensates intermodulation distortion by using a second harmonic extracted by a filter circuit. Recently, there arises the following issue: introduction of new communication standards, such as the fourth-generation mobile communication system (4G) and the fifth-generation mobile communication system (5G), causes an increase of the number of frequency bands with which a Doherty amplifier circuit is to be compatible; accordingly, the number of filter circuits increases, resulting in an increase of circuit size. When the configuration of the device described in Japanese Unexamined Patent Application Publication No. 2005-318373 is applied to a Doherty amplifier circuit, it is necessary to ensure the isolation between the device described in Japanese Unexamined Patent Application Publication No. 2005-318373 and the Doherty amplifier circuit not to affect operations of the Doherty amplifier circuit. This provides a necessity of even more λ/4 lines. This arises a problem of an increase of circuit size.

The present disclosure is made in view of the situation, and a possible benefit thereof is to provide a Doherty amplifier circuit which achieves the suppression of the influence of the intermodulation distortion with a reduction of circuit size.

To attain the possible benefit, a Doherty amplifier circuit according to an aspect of the present disclosure includes a 90° hybrid coupler including an input terminal that receives a first input signal, a first output terminal that outputs a first output signal on the basis of the first input signal, a second output terminal that outputs a second output signal on the basis of the first input signal, the second output signal being different in phase by 90° from the first output signal, and an isolation terminal whose isolation from the input terminal is ensured; a carrier amplifier that amplifies the first output signal to output a first amplified signal; and a peak amplifier that amplifies the second output signal to output a second amplified signal. The isolation terminal is a terminal receiving a second harmonic in a second harmonic frequency band of the first input signal.

The present disclosure may provide a Doherty amplifier circuit which achieves the suppression of the influence of the intermodulation distortion with a reduction of circuit size.

### BRIEF DESCRIPTION OF THE SEVERAL VIEWS OF THE DRAWINGS

FIG. 1 is a diagram illustrating a configuration example of a Doherty amplifier circuit according to a first embodiment;

FIG. 2 is a diagram illustrating a spectrum of an input signal RFin supplied to a driver amplifier;

FIG. 3 is a diagram illustrating cancellation of third intermodulation distortion of a signal RF10 outputted from a driver amplifier;

FIG. 4 is a graph illustrating bandpass characteristics of a signal received from an isolation terminal Tiso of a 90° hybrid coupler;

FIG. 5 is a diagram illustrating a configuration example of a Doherty amplifier circuit according to a first modified example;

FIG. 6 is a diagram illustrating a configuration example of a Doherty amplifier circuit according to a second modified example;

FIG. 7 is a diagram illustrating a configuration example of a Doherty amplifier circuit according to a third modified example;

FIG. 8 is a diagram illustrating a configuration example of a Doherty amplifier circuit according to a second embodiment; and

FIG. 9 is a diagram illustrating a configuration example of a Doherty amplifier circuit according to a fourth modified example.

### DETAILED DESCRIPTION OF THE DISCLOSURE

Embodiments of the present disclosure will be described below in detail by referring to the drawings. The same components are designated with the same reference numerals, and repeated description will be avoided.

Doherty Amplifier Circuit 100 according to First Embodiment

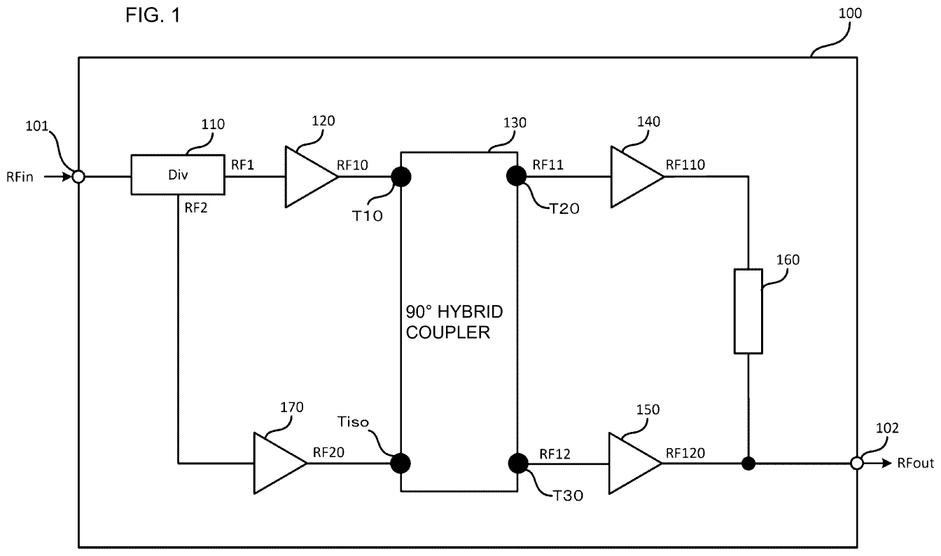

FIG. 1 is a diagram illustrating a configuration example of a Doherty amplifier circuit 100 according to a first embodiment. The Doherty amplifier circuit 100 illustrated in FIG. 1, which is included, for example, in a mobile communication device such as a cellular phone, is used to amplify the power of a radio-frequency (RF) signal which is to be transmitted to a base station. The Doherty amplifier circuit 100 amplifies the power of a signal, for example, of a communication standard, such as the second-generation mobile communication system (2G), the third-generation mobile communication system (3G), the fourth-generation mobile communication system (4G), the fifth-generation mobile communication system (5G), long term evolution (LTE)-frequency division duplex (FDD), LTE-time division duplex (TDD), LTE-Advanced, LTE-Advanced Pro, or the sixth-generation mobile communication system (6G). The frequency of an RF signal is, for example, about several hundreds of MHz to several tens of GHz. The communication standard and the frequency of a signal amplified by the Doherty amplifier circuit 100A are not limited to these.

Without use of a filter circuit for ensuring isolation, the Doherty amplifier circuit 100 may compensate third intermodulation distortion with a reduction of circuit size, achieving improvement of linearity.

The Doherty amplifier circuit 100 includes, for example, a divider 110, a driver amplifier 120, a 90° hybrid coupler 130, a carrier amplifier 140, a peak amplifier 150, a phase shifter 160, a second harmonic generator 170, an input terminal 101, and an output terminal 102.

The divider 110 divides, for example, an input signal RFin into a signal RF1 and a signal RF2 having a phase different by about 180° from that of the signal RF1. The term “about 180°” implies, for example, the range from 135° to 225°. The divider 110 includes, for example, a balun transformer. The divider 110 may have a function of matching the impedance between a preceding circuit (not illustrated) and the driver amplifier 120 which is a subsequent circuit.

The driver amplifier 120 amplifies the signal RF1 received through the divider 110, and outputs a signal RF10 to an input terminal T10 of the 90° hybrid coupler 130.

The 90° hybrid coupler 130 divides the signal RF10, which is outputted from the driver amplifier 120, into two signals having the same power but having phases different from each other by 90°. The 90° hybrid coupler 130 includes the input terminal T10, a first output terminal T20, a second output terminal T30, and an isolation terminal Tiso.

The 90° hybrid coupler 130 may include, for example, two transmission lines (for example, λ/4 lines) which are electromagnetically coupled to each other. The two transmission lines are, for example, strip lines or microstrip lines which are provided in or on a substrate. The two transmission lines are both formed so as to extend in a certain direction in plan view of the power amplifier 100.

The input terminal T10, which is a first end of a first one of the transmission lines, receives the signal RF10 through the driver amplifier 120. The second output terminal T30, which is a second end of the first one of the transmission lines, outputs a signal RF12 obtained by dividing the signal RF10. The first output terminal T20, which is a first end of a second one of the transmission lines, outputs a signal RF11 obtained by dividing the signal RF10. The phase of the signal RF12 is delayed by about 90° with respect to that of the signal RF11.

The isolation terminal Tiso, which is a second end of the second one of the transmission lines, is a terminal whose isolation from the input terminal T10 is ensured. That is, even when the input terminal T10 receives the signal RF10, no voltage occurs at the isolation terminal Tiso. The isolation terminal Tiso, whose isolation from the other terminal is ensured, receives a second harmonic RF20 outputted from the second harmonic generator 170.

The Doherty amplifier circuit 100 has a configuration in which the isolation terminal Tiso, which is isolated from the input terminal T10, receives the second harmonic RF20. Thus, without use of a filter circuit for ensuring isolation, third intermodulation distortion may be compensated. This achieves a reduction of the circuit size.

The 90° hybrid coupler 130 is not limited to having two transmission lines which are electromagnetically coupled to each other. For example, the 90° hybrid coupler 130 may have a configuration, for example, in which four microstrip lines each having a length of λ/4 are connected to each other to be shaped like a rectangle. In this case, the Doherty amplifier circuit 100 has a configuration in which the second harmonic RF20, which is outputted from the second harmonic generator 170, is received by a terminal whose isolation from the other terminal is ensured.

The carrier amplifier 140 amplifies the signal RF11, which is outputted from the first output terminal T20 of the 90° hybrid coupler 130, and outputs a signal RF110. The carrier amplifier 140 operates irrespective of the voltage level of the signal RF11. That is, the carrier amplifier 140 operates when the power level of the signal RF11 is higher than zero.

The peak amplifier 150 amplifies the signal RF12, which is outputted from the second output terminal T30 of the 90° hybrid coupler 130, and outputs a signal RF120. The peak amplifier 150 operates when the voltage level of the signal RF12 is in a range between the maximum level and a predetermined lower level. For example, the peak amplifier 150 operates when the power level of the signal RF12 is in a range at and above a level lower by 3 dB than the maximum level.

The phase shifter 160 is, for example, a quarter-wave line connected to the output side of the carrier amplifier 140. Thus, the load impedance as seen from the output end of the carrier amplifier 140 may be changed to achieve high efficiency of the Doherty amplifier 100.

The second harmonic generator 170 is a circuit generating, from the signal RF2 obtained through division by the divider 110, the second harmonic RF20 which is a second harmonic signal for compensating the third intermodulation distortion in the Doherty amplifier circuit. The second harmonic generator 170 outputs the generated second harmonic RF20 to the isolation terminal Tiso of the 90° hybrid coupler 130. For example, the second harmonic generator 170 removes the fundamental of the signal RF2 obtained through division by the divider 110, and amplifies the signal in the second harmonic frequency band of the signal RF2. The second harmonic generator 170 may generate the second harmonic RF20 through the adjustment of the phase of the amplitude of the signal RF2. That is, for the output of the second harmonic RF20, the second harmonic generator 170 may adjust the signal RF2 so that the signal RF2 has a phase and an amplitude which are suitable for the compensation of third intermodulation distortion.

Each amplifier includes, for example, a bipolar transistor such as a heterojunction bipolar transistor (HBT). Each amplifier may include a metal-oxide-semiconductor field-effect transistor (MOSFET) instead of an HBT.

The Doherty amplifier circuit 100 which includes the second harmonic generator 170 is described above. However, the configuration is not limited to this. The Doherty amplifier circuit 100 does not necessarily include the second harmonic generator 170. In this case, the Doherty amplifier circuit 100 may have any configuration as long as the isolation terminal Tiso receives the second harmonic RF20 from another circuit. This achieves a reduction in size of the Doherty amplifier circuit 100.

### Operation of Compensating Third Intermodulation Distortion

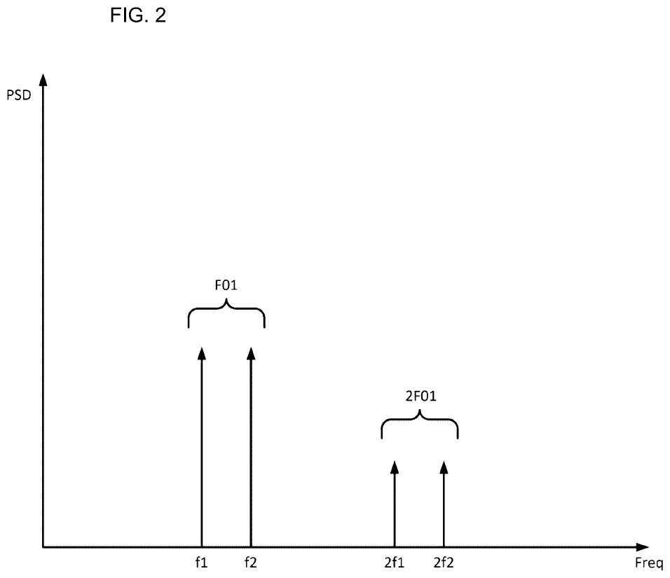

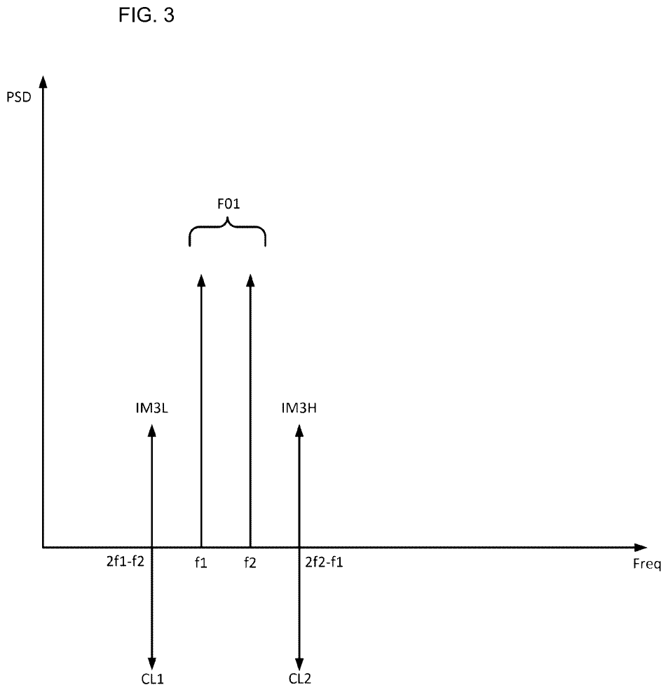

Referring to FIGS. 2 and 3, an operation of compensating the third intermodulation distortion in the Doherty amplifier circuit 100 will be described. FIG. 2 is a diagram illustrating the spectrum of the input signal RFin supplied to the peak amplifier 150. Signal components of the second harmonic of the signal RF12 cause third intermodulation distortion to occur. FIG. 3 is a diagram illustrating cancellation of third intermodulation distortion of the signal RF120 outputted from the peak amplifier 150. In FIGS. 2 and 3, the horizontal axis indicates signal frequency; the vertical axis indicates power spectral density (PSD).

As illustrated in FIG. 2, the carrier amplifier 140 and the peak amplifier 150 are supplied with a fundamental signal F₀₁ and a second harmonic signal 2F₀₁ that are included in the signal RF11 and the signal RF12 which are generated through the 90° hybrid coupler 130. The fundamental signal F₀₁ includes components of two frequencies f₁ and f₂ (f₁<f₂) which are close to each other. That is, the Doherty amplifier circuit 100 is supplied with a signal obtained by combining the signal F₀₁ of the frequencies f₁ and f₂ and the signal 2F₀₁ of frequencies 2f₁ and 2f₂.

As illustrated in FIG. 3, in the carrier amplifier 140 and the peak amplifier 150 which have nonlinearity, an operation of amplifying the fundamental causes a third intermodulation distortion IM3_{L} at a frequency of 2f₁−f₂ to occur in the lower range of a fundamental (of the frequency f₁) of the signal F₀₁, and causes a third intermodulation distortion IM3_{H} at a frequency of 2f₂−f₁ to occur in the higher range of a fundamental (of the frequency f₂) of the signal Fol.

The third intermodulation distortions IM3_{L} and IM3_{H} are relatively close to the frequencies f₁ and f₂ of the fundamental signal F₀₁. Therefore, it is difficult to remove the third intermodulation distortions IM3_{L} and IM3_{H}, for example, by using a filter circuit. The third intermodulation distortions IM3_{L} and IM3_{H} are a cause of degradation in characteristics of the Doherty amplifier circuit 100.

Therefore, as illustrated in FIG. 3, the Doherty amplifier circuit 100 combines the second harmonic RF20 with the fundamental signal F₀₁ on purpose so as to generate compensation signals CL₁ and CL₂ for cancelling the third intermodulation distortions IM3_{L} and IM3_{H}.

Specifically, the Doherty amplifier circuit 100 amplifies the signal, which is obtained by the 90° hybrid coupler 130 combining the fundamental signal F₀₁ with the second harmonic RF20, by using each of the carrier amplifier 140 and the peak amplifier 150. The Doherty amplifier circuit 100 generates the compensation signal CL₁ having the frequency (2f₁−f₂) which is the difference between the frequency 2f₁, which is a first one of the frequencies of the second harmonic RF20, and the frequency f₂, which is a second one of the frequencies of the fundamental signal F₀₁. The Doherty amplifier circuit 100 generates the compensation signal CL₂ having the frequency (2f₂−f₁) which is the difference between the frequency 2f₂, which is a second one of the frequencies of the second harmonic RF20, and the frequency f₁, which is a first one of the frequencies of the fundamental signal Fol.

That is, in the Doherty amplifier circuit 100, the isolation terminal Tiso of the 90° hybrid coupler 130 receives the second harmonic RF20 obtained through such adjustment that, at the output of the carrier amplifier 140 and the peak amplifier 150, the third intermodulation distortions IM3_{L} and IM3_{H}, which occur due to amplification operations of the carrier amplifier 140 and the peak amplifier 150, are different in phase by about 180° from the compensation signals CL₁ and CL₂.

Further, in the Doherty amplifier circuit 100, the isolation terminal Tiso of the 90° hybrid coupler 130 receives the second harmonic RF20 whose amplitude is adjusted so that, at the output of the carrier amplifier 140 and the peak amplifier 150, the amplitudes of the third intermodulation distortions IM3_{L} and IM3_{H}, which occur at the carrier amplifier 140 and the peak amplifier 150, are cancelled with the amplitudes of the compensation signals CL₁ and CL₂.

Due to the operation described above, without use of a filter circuit for ensuring isolation, the Doherty amplifier circuit 100 achieves the suppression of the influence of the third intermodulation distortions IM3_{L} and IM3_{H}, which occur through amplification operations of the carrier amplifier 140 and the peak amplifier 150. The Doherty amplifier circuit 100 achieves the suppression of the degradation of linearity in the Doherty amplifier circuit.

### Details of Compensation Operation for the Peak Amplifier 150

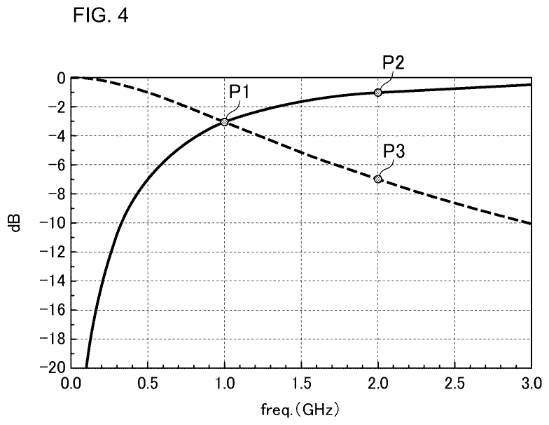

Referring to FIG. 4, the point in which use of the 90° hybrid coupler 130 in the Doherty amplifier circuit 100 enables improvement of the linearity of the peak amplifier 150 will be described. FIG. 4 is a graph illustrating bandpass characteristics of a signal received from the isolation terminal Tiso of the 90° hybrid coupler 130. In FIG. 4, the horizontal axis indicates signal frequency; the vertical axis indicates signal strength. In FIG. 4, for example, a dashed line indicates bandpass characteristics of a signal passing through the first output terminal T20; a solid line indicates bandpass characteristics of a signal passing through the second output terminal T30.

In the Doherty amplifier circuit, the linearity of the peak amplifier 150, which operates in a range of higher input voltage level, degrades compared with the carrier amplifier 140. The Doherty amplifier circuit 100 causes a larger amount of the second harmonic RF20 to pass through the peak amplifier 150, whose linearity remarkably degrades, than the carrier amplifier 140. Thus, the Doherty amplifier circuit 100 may suppress the degradation of linearity in the Doherty amplifier circuit. For example, description will be made below under the assumption that the 90° hybrid coupler 130 operates as a 3-dB coupler with respect to a 1-GHz signal.

As illustrated in FIG. 4, when the isolation terminal Tiso receives, for example, a 1-GHz signal, the 90° hybrid coupler 130 outputs signals of the same signal strength from the first output terminal T20 connected to the carrier amplifier 140 and the second output terminal T30 connected to the peak amplifier 150 (“P1” in FIG. 4).

In the 90° hybrid coupler 130, when the isolation terminal Tiso receives, for example, a 2-GHz signal which is the second harmonic of a 1-GHz signal, a signal outputted from the first output terminal T20 connected to the carrier amplifier 140 has power of −6.990 dB (“P2” in FIG. 4, and the power ratio to the signal received by the isolation terminal Tiso is 0.2); a signal outputted from the second output terminal T30 connected to the peak amplifier 150 has power of −0.969 dB (“P3” in FIG. 4, and the power ratio to the signal received by the isolation terminal Tiso is 0.8).

That is, in the 90° hybrid coupler 130, the second harmonic outputted to the peak amplifier 150 has power four times higher than the second harmonic outputted to the carrier amplifier 140.

Due to the operation described above, without use of a filter circuit for ensuring isolation, the Doherty amplifier circuit 100 further suppresses the influence of the third intermodulation distortions IM3_{L} and IM3_{H} which occur through an amplification operation of the peak amplifier 150 whose linearity remarkably degrades. Thus, the Doherty amplifier circuit 100 achieves the improvement of linearity in the Doherty amplifier circuit.

### First Modified Example

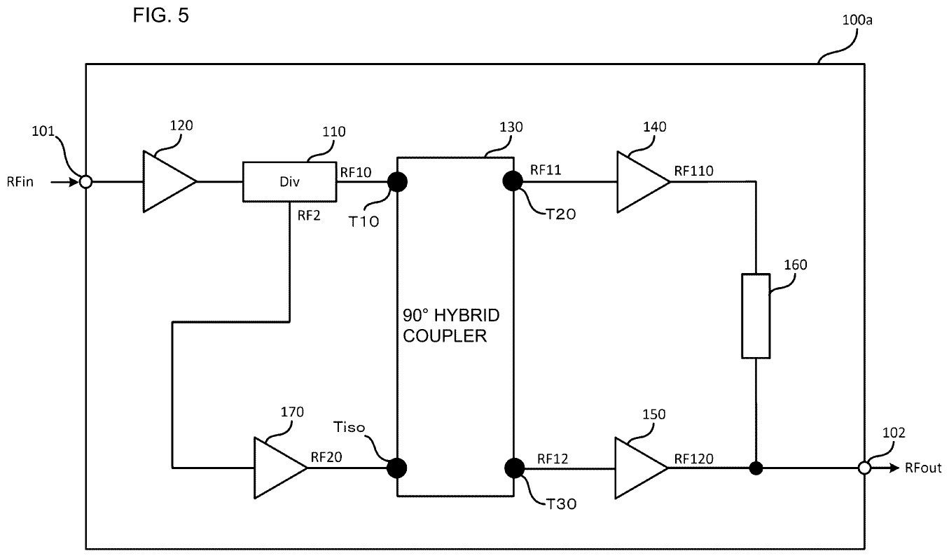

Referring to FIG. 5, a Doherty amplifier circuit 100a according to a first modified example will be described. FIG. 5 is a diagram illustrating a configuration example of the Doherty amplifier circuit 100a according to the first modified example. In the description below, points common to the Doherty amplifier circuit 100 according to the first embodiment will not be described, and only different points will be described. In particular, substantially the same operational effects caused by substantially the same configurations will not be described.

Compared with the Doherty amplifier circuit 100 in FIG. 1, in the Doherty amplifier circuit 100a, the divider 160 is disposed downstream of the driver amplifier 120. Specifically, the driver amplifier 120 outputs, to the divider 110, a signal obtained by amplifying the input signal RFin. The divider 160 divides, for example, a signal, which has been amplified by the driver amplifier 120, into the signal RF10 and the signal RF2 having a phase different by about 180° from that of the signal RF10. The input terminal T10 of the 90° hybrid coupler 130 receives the signal RF10; the isolation terminal Tiso receives the signal RF2 through the second harmonic generator 170.

Thus, compared with the Doherty amplifier circuit 100, in the Doherty amplifier circuit 100a, the isolation terminal Tiso of the 90° hybrid coupler 130 may receive the second harmonic RF20 having larger power. Thus, the Doherty amplifier circuit 100a achieves a reduction of circuit size without use of a filter circuit for ensuring isolation, and reliably suppresses the influence of the third intermodulation distortions IM3_{L} and IM3_{H} which occur at the carrier amplifier 140 and the peak amplifier 150, achieving improvement of linearity.

### Second Modified Example

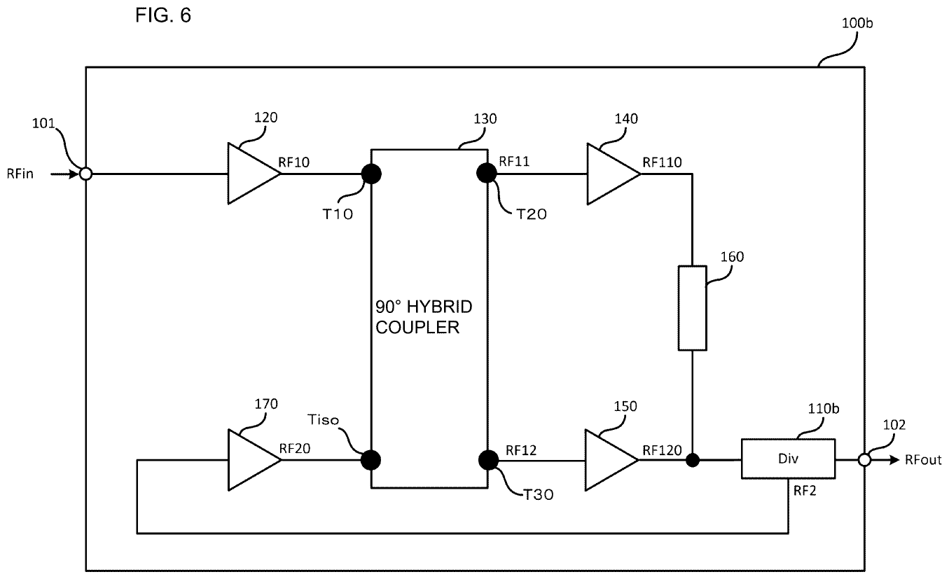

Referring to FIG. 6, a Doherty amplifier circuit 100b according to a second modified example will be described. FIG. 6 is a diagram illustrating a configuration example of the Doherty amplifier circuit 100b according to the second modified example. In the description below, points common to the Doherty amplifier circuit 100 according to the first embodiment will not be described, and only different points will be described. In particular, substantially the same operational effects caused by substantially the same configurations will not be described.

Compared with the Doherty amplifier circuit 100 in FIG. 1, in the Doherty amplifier circuit 100b, a divider 110b is disposed downstream of the carrier amplifier 140 and the peak amplifier 150. Specifically, the driver amplifier 120 outputs, to the input terminal T10 of the 90° hybrid coupler 130, the signal RF10 obtained by amplifying the input signal RFin. The divider 110b divides a signal, which is obtained by combining the signal RF110 outputted from the carrier amplifier 140 with the signal RF120 outputted from the peak amplifier 150, into the output signal RFout outputted to the output terminal 102 and the signal RF2 inputted to the second harmonic generator 170. The second harmonic generator 170 generates the second harmonic RF20 from the signal RF2 for outputting to the isolation terminal Tiso of the 90° hybrid coupler 130.

Thus, compared with the Doherty amplifier circuit 100, in the Doherty amplifier circuit 100b, the isolation terminal Tiso of the 90° hybrid coupler 130 may receive the second harmonic RF20 having larger power. Thus, the Doherty amplifier circuit 100b achieves a reduction of circuit size without use of a filter circuit for ensuring isolation, and more reliably suppresses the influence of the third intermodulation distortions IM3_{L} and IM3_{H} which occur at the carrier amplifier 140 and the peak amplifier 150, achieving improvement of linearity.

### Third Modified Example

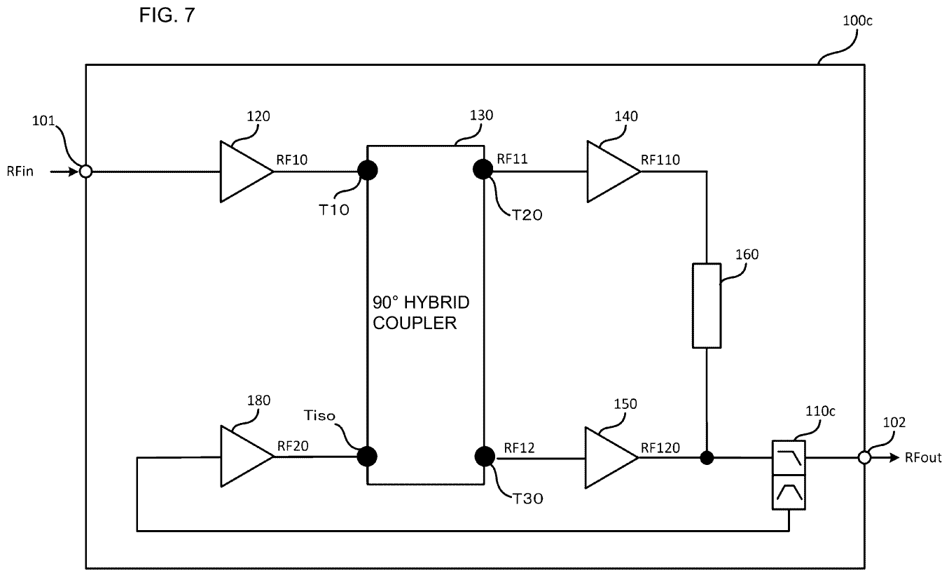

Referring to FIG. 7, a Doherty amplifier circuit 100c according to a third modified example will be described. FIG. 7 is a diagram illustrating a configuration example of the Doherty amplifier circuit 100c according to the third modified example. In the description below, points common to the Doherty amplifier circuit 100 according to the first embodiment will not be described, and only different points will be described. In particular, substantially the same operational effects caused by substantially the same configurations will not be described.

The Doherty amplifier circuit 100c is a circuit having the configuration of the Doherty amplifier circuit 100b in FIG. 6 except that the divider 110 is replaced with a separator 110c and that the second harmonic generator 170 is replaced with a second harmonic amplifier 180.

The separator 110c is a diplexer which separates second harmonic components from the signal obtained by combining the signal RF110 outputted from the carrier amplifier 140 with the signal RF120 outputted from the peak amplifier 150. For example, the separator 110c is a circuit of a combination of a low-pass filter and a bandpass filter. The separator 110c passes, to the output terminal 102, the fundamental signal as the output signal RFout, and separates the second harmonic for outputting to the second harmonic amplifier 180. The second harmonic amplifier 180 amplifies the second harmonic received from the separator 110c, for outputting to the isolation terminal Tiso of the 90° hybrid coupler 130.

Thus, in the Doherty amplifier circuit 100c, compared with the Doherty amplifier circuit 100, the isolation terminal Tiso of the 90° hybrid coupler 130 may receive the second harmonic RF20 having larger power. Thus, the Doherty amplifier circuit 100c may more reliably suppress the influence of the third intermodulation distortions IM3_{L} and IM3_{H} which occur at the carrier amplifier 140 and the peak amplifier 150, without use of a filter circuit for ensuring isolation.

The Doherty amplifier circuit 100c, which includes the second harmonic amplifier 180, is described above. However, the configuration is not limited to this. The Doherty amplifier circuit 100c does not necessarily include the second harmonic amplifier 180. In this case, the Doherty amplifier circuit 100c may have any configuration as long as, through the adjustment of the design conditions, for example, of the driver amplifier 120, the carrier amplifier 140, and the peak amplifier 150, a second harmonic received at the isolation terminal Tiso of the 90° hybrid coupler 130 is designed. Thus, the Doherty amplifier circuit 100 achieves a reduction of circuit size.

Doherty Amplifier Circuit 100d according to Second Embodiment

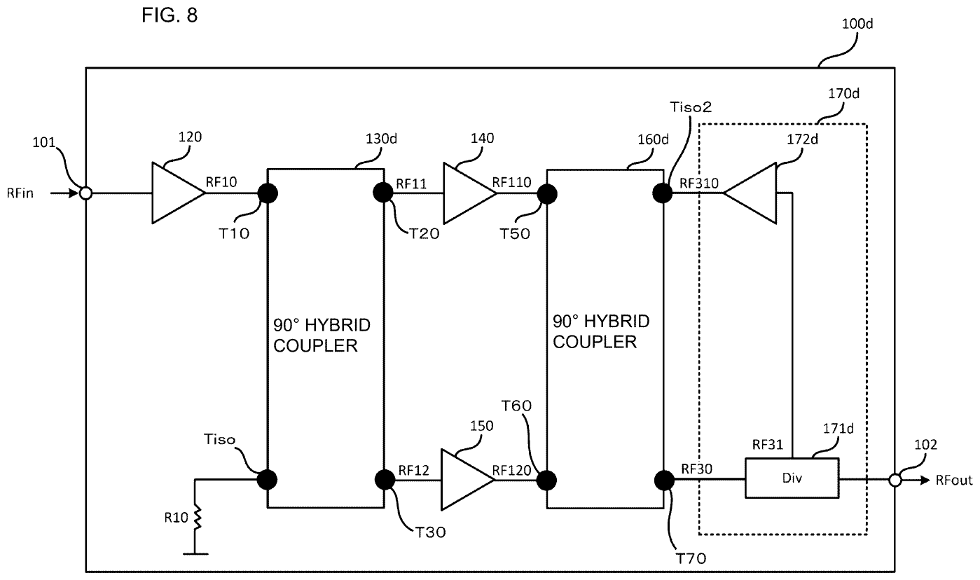

Referring to FIG. 8, a Doherty amplifier circuit 100d according to a second embodiment will be described. FIG. 8 is a diagram illustrating a configuration example of the Doherty amplifier circuit 100d according to the second embodiment. In the description below, points common to the Doherty amplifier circuit 100 according to the first embodiment will not be described, and only different points will be described. In particular, substantially the same operational effects caused by substantially the same configurations will not be described.

Compared with the Doherty amplifier circuit 100 in FIG. 1, the Doherty amplifier circuit 100d includes a 90° hybrid coupler 160d instead of the phase shifter 160 on the output side of the carrier amplifier 140 and the peak amplifier 150. The Doherty amplifier circuit 100d has a configuration in which an isolation terminal Tiso2, whose isolation from an output terminal T70 of the 90° hybrid coupler 160d is ensured, receives a second harmonic RF310 from a harmonic generating unit 170d. Thus, the Doherty amplifier circuit 100d suppresses the influence of the third intermodulation distortions IM3_{L} and IM3_{H}, which occur at the carrier amplifier 140 and the peak amplifier 150, by combining the second harmonic on the output side.

In FIG. 8, a 90° hybrid coupler 130d is used. However, the configuration is not limited to this. Any configuration may be employed as long as, for example, the 90° hybrid coupler 130d is a divider which divides the signal RF10 into the signal RF11 and the signal RF12 having a phase different by 90° from that of the signal RF11.

The 90° hybrid coupler 160d combines the signal RF110 outputted from the carrier amplifier 140 with the signal RF120 which is outputted from the peak amplifier 150 and which has a phase different by 90° from that of the signal RF110. The 90° hybrid coupler 160d has the bandpass characteristics illustrated in FIG. 4. The 90° hybrid coupler 160d includes a first input terminal T50, a second input terminal T60, the output terminal T70, and the isolation terminal Tiso2.

The 90° hybrid coupler 160d may include, for example, two transmission lines (for example, λ/4 lines) which are electromagnetically coupled to each other. The two transmission lines are, for example, strip lines or microstrip lines which are disposed in or on a substrate. The two transmission lines are both formed so as to extend in a certain direction in plan view of the Doherty amplifier circuit 100d.

The first input terminal T50, which is a first end of a first one of the transmission lines, receives the signal RF110 from the carrier amplifier 140. The output terminal T70, which is a second end of the first one of the transmission lines, outputs a combined signal RF30 obtained by combining the signal RF110 with the RF150 outputted from the peak amplifier 150. The second input terminal T60, which is a first end of a second one of the transmission lines, receives the signal RF120 from the peak amplifier 150. The 90° hybrid coupler 160d combines the signal RF120 with a signal obtained by delaying the phase of the input signal RF110 by about 90°, and outputs the combined signal RF30 from the output terminal T70.

The isolation terminal Tiso2, which is a second end of the second one of the transmission lines, is a terminal whose isolation from the output terminal T70 is ensured. That is, even when the signal RF110 and the signal RF120 are received at the first input terminal T50 and the second input terminal T60, no voltage occurs at the isolation terminal Tiso2. The isolation terminal Tiso2 receives the second harmonic RF310 outputted from the harmonic generating unit 170d described below.

The harmonic generating unit 170d includes, for example, a divider 171d and a second harmonic generator 172d. The divider 171d includes, for example, a balun transformer. For example, the divider 171d divides the combined signal RF30 into the output signal RFout and a signal RF31 having a phase different from that of the output signal RFout by about 180°. The second harmonic generator 172d is a circuit which generates the second harmonic RF310, which is a second harmonic signal for compensating the third intermodulation distortion in the Doherty amplifier circuit, from the signal RF31 obtained through division by the divider 171d. The second harmonic generator 172d has substantially the same configuration as that of the second harmonic generator 170 of the Doherty amplifier circuit 100.

Thus, without use of a filter circuit for ensuring isolation, the Doherty amplifier circuit 100d suppresses the influence of the third intermodulation distortions IM3_{L} and IM3_{H}, which occur at the carrier amplifier 140 and the peak amplifier 150, achieving improvement of linearity.

### Fourth Modified Example

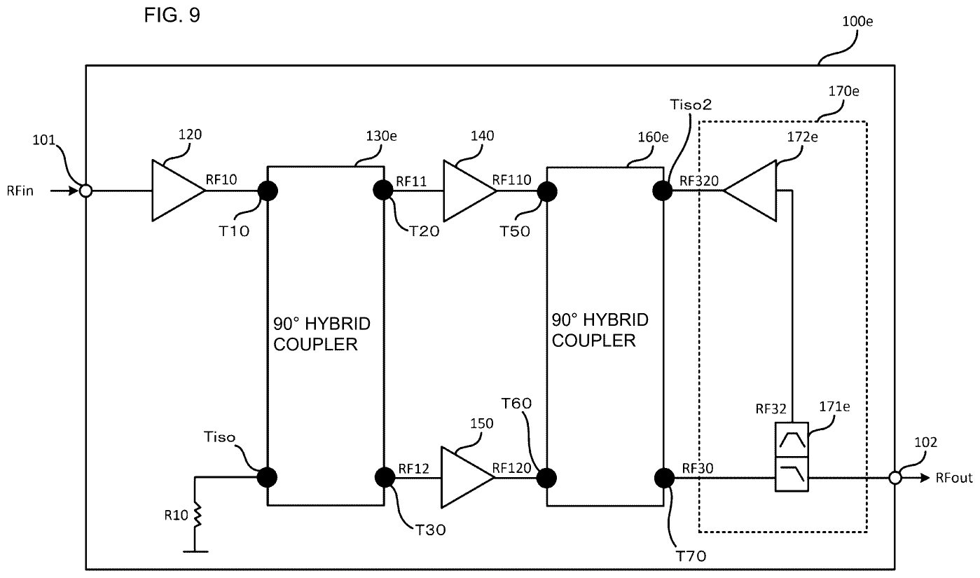

Referring to FIG. 9, a Doherty amplifier circuit 100e according to a fourth modified example will be described. FIG. 9 is a diagram illustrating a configuration example of the Doherty amplifier circuit 100e according to the fourth modified example. In the description below, points common to the Doherty amplifier circuit 100d according to the second embodiment will not be described, and only different points will be described. In particular, substantially the same operational effects caused by substantially the same configurations will not be described.

Compared with the Doherty amplifier circuit 100d, the Doherty amplifier circuit 100e is a circuit in which, for example, the divider 171d is replaced with a separator 171e and the second harmonic generator 172d is replaced with a second harmonic amplifier 172e.

The separator 171e is a diplexer which separates second harmonic components from a signal that is obtained by combining the signal RF110 outputted from the carrier amplifier 140 with the signal RF120 outputted from the peak amplifier 150, and that is outputted from the output terminal T70 of the 90° hybrid coupler 160e. For example, the separator 171e is a circuit of combination of a low-pass filter and a bandpass filter. The separator 171e passes, to the output terminal 102, the fundamental signal as the output signal RFout, and separates the second harmonic for outputting to the second harmonic amplifier 172e. The second harmonic amplifier 172e amplifies the second harmonic received from the separator 171e, for outputting to the isolation terminal Tiso2 of the 90° hybrid coupler 160e.

Thus, without use of a filter circuit for ensuring isolation, the Doherty amplifier circuit 100e suppresses the influence of the third intermodulation distortions IM3_{L} and IM3_{H}, which occur at the carrier amplifier 140 and the peak amplifier 150, achieving improvement of linearity. The Doherty amplifier circuit 100e, which includes the second harmonic amplifier 172e, is described above. However, the configuration is not limited to this. The Doherty amplifier circuit 100e does not necessarily include the second harmonic amplifier 172e. In this case, the Doherty amplifier circuit 100e is such a circuit that a second harmonic which is to be received at the isolation terminal Tiso2 of the 90° hybrid coupler 160e is designed through the adjustment of design conditions, for example, of the carrier amplifier 140 and the peak amplifier 150. Thus, the Doherty amplifier circuit 100e achieves a reduction of circuit size.

### CONCLUSION

<1> The Doherty amplifier circuit 100 according to an exemplary embodiment of the present disclosure comprises the 90° hybrid coupler 130 that includes the input terminal T10 which receives the signal RF1 (first input signal), the first output terminal T20 which outputs the signal RF11 (first output signal) on the basis of the signal RF1 (first input signal), the second output terminal T30 which, on the basis of the signal RF1 (first input signal), outputs the signal RF12 (second output signal) different in phase by 90° from the signal RF11 (first output signal), and the isolation terminal Tiso whose isolation from the input terminal T10 is ensured; the carrier amplifier 140 that amplifies the signal RF11 (first output signal) to output the signal RF110 (first amplified signal); and the peak amplifier 150 that amplifies the signal RF12 (second output signal) to output the signal RF120 (second amplified signal). The isolation terminal Tiso is a terminal receiving the second harmonic RF20 in the second harmonic frequency band of the signal RF1 (first input signal). Thus, while reducing the circuit size without use of a filter circuit for ensuring isolation, the Doherty amplifier circuit 100 compensates third intermodulation distortion, achieving improvement of linearity.

<2> In the Doherty amplifier circuit 100 according to the exemplary embodiment of the present disclosure, the Doherty amplifier circuit according to <1> further comprises the divider 110 that is connected in series to the input terminal 101 (terminal) receiving an input signal and to the input terminal T10 and that divides the input signal RFin into the signal RF1 (first input signal) and the signal RF2 (second input signal); and the second harmonic generator 170 that generates the second harmonic RF20 on the basis of the signal RF2 (second input signal) to output the second harmonic RF20 to the isolation terminal Tiso. Thus, while reducing the circuit size without use of a filter circuit for ensuring isolation, the Doherty amplifier circuit 100 compensates third intermodulation distortion, achieving improvement of linearity.

<3> In the Doherty amplifier circuit 100 according to the exemplary embodiment of the present disclosure, the Doherty amplifier circuit according to <2> further comprises the driver amplifier 120 that outputs, to the input terminal T10, a signal obtained by amplifying the signal RF1 (first input signal). Thus, while reducing the circuit size without use of a filter circuit for ensuring isolation, the Doherty amplifier circuit 100 compensates third intermodulation distortion, achieving improvement of linearity.

<4> In the Doherty amplifier circuit 100a according to an exemplary embodiment of the present disclosure, the Doherty amplifier circuit according to <2> further comprises the driver amplifier 120 that outputs a signal obtained by amplifying the input signal RFin; and the divider 110 that divides the signal into the signal RF10 (first input signal) and the signal RF2 (second input signal). Thus, while reducing the circuit size without use of a filter circuit for ensuring isolation, the Doherty amplifier circuit 100a more reliably suppresses the influence of third intermodulation distortion which occurs at the carrier amplifier 140 and the peak amplifier 150, achieving improvement of linearity.

<5> In the Doherty amplifier circuit 100b according to an exemplary embodiment of the present disclosure, the Doherty amplifier circuit according to <1> further comprises the divider 110b that divides a combined signal, which is obtained by combining the signal RF110 (first amplified signal) with the signal RF120 (second amplified signal), into the output signal RFout outputted to the output terminal 102 and the signal RF2 (third input signal) illustrated in FIG. 6; and the second harmonic generator 170 that generates the second harmonic RF20 on the basis of the signal RF2 (third input signal) illustrated in FIG. 6, and that outputs the second harmonic RF20 to the isolation terminal Tiso. Thus, while reducing the circuit size without use of a filter circuit for ensuring isolation, the Doherty amplifier circuit 100b more reliably suppresses the influence of third intermodulation distortion which occurs at the carrier amplifier 140 and the peak amplifier 150, achieving improvement of linearity.

<6> In the Doherty amplifier circuit 100c according to an exemplary embodiment of the present disclosure, the Doherty amplifier circuit according to <1> further comprises the separator 110c that separates the components of the second harmonic RF20 from a combined signal obtained by combining the signal RF110 (first amplified signal) with the signal RF120 (second amplified signal), and that outputs the second harmonic RF20 to the isolation terminal Tiso. Thus, while reducing the circuit size without use of a filter circuit for ensuring isolation, the Doherty amplifier circuit 100c may more reliably suppress the influence of third intermodulation distortion which occurs at the carrier amplifier 140 and the peak amplifier 150.

<7> In the Doherty amplifier circuit 100c according to the exemplary embodiment of the present disclosure, the Doherty amplifier circuit according to <6> further comprises the second harmonic amplifier 180 that amplifies, for outputting to the isolation terminal Tiso, the second harmonic RF20 outputted from the separator. Thus, while reducing the circuit size without use of a filter circuit for ensuring isolation, the Doherty amplifier circuit 100c may more reliably suppress the influence of third intermodulation distortion which occurs at the carrier amplifier 140 and the peak amplifier 150.

<8> The Doherty amplifier circuit 100d, 100e according to an exemplary embodiment of the present disclosure comprises a divider 130e that divides the signal RF10 (input signal) into the signal RF11 (first output signal) and the signal 12 (second output signal) different in phase by 90° from the signal RF11 (first output signal); the carrier amplifier 140 that amplifies the signal RF11 (first output signal) to output the signal 110 (first amplified signal); the peak amplifier 150 that amplifies the signal 12 (second output signal) to output the signal RF120 (second amplified signal); the 90° hybrid coupler 160d, 160e that includes the first input terminal T50 which receives the signal RF110 (first amplified signal), the second input terminal T60 which receives the signal RF120 (second amplified signal), the output terminal T70 which combines the signal RF110 (first amplified signal) with the signal 120 (second amplified signal) to output the combined signal RF30, and the isolation terminal Tiso2 whose isolation from the output terminal T70 is ensured; and the harmonic generating unit 170e that, on the basis of the combined signal RF30, outputs, to the isolation terminal Tiso2, the second harmonic RF310, RF320 in the second harmonic frequency band of the combined signal RF30. Thus, while reducing the circuit size without use of a filter circuit for ensuring isolation, the Doherty amplifier circuit 100d, 100e may suppress the influence of third intermodulation distortion which occurs at the carrier amplifier 140 and the peak amplifier 150.

The embodiments described above are made to facilitate understanding of the present disclosure, not to interpret the present disclosure limitedly. The present disclosure may be changed or improved without departing from the gist thereof, and encompasses the equivalents. That is, embodiments, which are obtained by those skilled in the art adding appropriate design change to the embodiments, are also encompassed in the scope of the present disclosure as long as they have features of the present disclosure. For example, the components, which are included in the embodiments, and their layouts, materials, conditions, shapes, sizes, and the like are not limited to illustrated ones, and may be changed appropriately. The components included in the embodiments may be combined with one another as long as the combinations are technically allowed. These combinations are also encompassed in the scope of the present disclosure as long as having features of the present disclosure.

What is claimed is:

1. A Doherty amplifier circuit comprising:
a 90° hybrid coupler comprising:
an input terminal configured to receive a first input signal,
a first output terminal configured to output a first output signal on the basis of the first input signal,
a second output terminal configured to output a second output signal on the basis of the first input signal, the second output signal being different in phase by 90° from the first output signal, and
an isolation terminal that is isolated from the input terminal;
a carrier amplifier configured to amplify the first output signal and to output a first amplified signal; and
a peak amplifier configured to amplify the second output signal and to output a second amplified signal,
wherein the isolation terminal is configured to receive a second harmonic in a second harmonic frequency band of the first input signal.

2. The Doherty amplifier circuit according to claim 1, further comprising:
a divider that is connected in series to a terminal that receives an input signal and to the input terminal, and that is configured to divide the input signal into the first input signal and a second input signal; and
a second harmonic generator configured to generate the second harmonic on the basis of the second input signal and to output the second harmonic to the isolation terminal.

3. The Doherty amplifier circuit according to claim 2, further comprising:
a driver amplifier configured to output, to the input terminal, a signal obtained by amplifying the first input signal.

4. The Doherty amplifier circuit according to claim 2, further comprising:
a driver amplifier configured to output a signal obtained by amplifying the input signal; and
a divider configured to divide the signal into the first input signal and the second input signal.

5. The Doherty amplifier circuit according to claim 1, further comprising:
a divider configured to divide a combined signal into an output signal outputted to an output terminal and a third input signal, the combined signal being obtained by combining the first amplified signal with the second amplified signal; and
a second harmonic generator configured to generate the second harmonic on the basis of the third input signal, and to output the second harmonic to the isolation terminal.

6. The Doherty amplifier circuit according to claim 1, further comprising:
a separator configured to separate a component of the second harmonic from a combined signal obtained by combining the first amplified signal with the second amplified signal, and to output the second harmonic to the isolation terminal.

7. The Doherty amplifier circuit according to claim 6, further comprising:
a second harmonic amplifier configured to amplify, for output to the isolation terminal, the second harmonic outputted from the separator.

8. A Doherty amplifier circuit comprising:
a divider configured to divide an input signal into a first output signal and a second output signal, the second output signal being different in phase by 90° from the first output signal;
a carrier amplifier configured to amplify the first output signal and to output a first amplified signal;
a peak amplifier configured to amplify the second output signal and to output a second amplified signal;
a 90° hybrid coupler that comprises:
a first input terminal configured to receive the first amplified signal,
a second input terminal configured to receive the second amplified signal,
an output terminal configured to combine the first amplified signal with the second amplified signal and to output a combined signal, and
an isolation terminal that is isolated from the output terminal; and
a harmonic generator that is configured to, on the basis of the combined signal, outputs, to the isolation terminal, a second harmonic in a second harmonic frequency band of the combined signal.
